(19) United States
(12) Patent Application Publication
(10) Pub. No.: US 2022/0098719 A1
(43) Pub. Date: Mar. 31, 2022

(54) MASK AND EVAPORATION SYSTEM

(71) Applicant: KunShan Go-Visionox Opto-Electronics Co., Ltd, Kunshan (CN)

(72) Inventors: Bing HAN, Kunshan (CN); Weili LI, Kunshan (CN); Mingxing LIU, Kunshan (CN)

(73) Assignee: KunShan Go-Visionox Opto-Electronics Co., Ltd, Kunshan (CN)

(21) Appl. No.: 17/546,384

(22) Filed: Dec. 9, 2021

Related U.S. Application Data
(63) Continuation of application No. PCT/CN2020/107946, filed on Aug. 7, 2020.

(30) Foreign Application Priority Data
Nov. 21, 2019 (CN) 201922027915.2

(51) Int. Cl. C23C 14/04; C23C 14/12; C23C 14/24

(52) U.S. Cl. CPC C23C 14/042; C23C 14/24; C23C 14/12

(57) ABSTRACT

A mask, and an evaporation system. The mask includes at least one magnetic plate body defining a plurality of openings. The magnetic plate body includes a bending body at a periphery of each of the plurality of openings; and the bending body has a certain thickness and width to make the bending body bendable toward a substrate which is configured to be evaporated under an action of a magnetic field generator.

### CROSS REFERENCE

The present application is a continuation-application of International (PCT) Patent Application No. PCT/CN2020/107946, filed on Aug. 7, 2020, which claims priority of Chinese Patent Application No. 201922027915.2, filed on Nov. 21, 2019, in the China National Intellectual Property Administration, the entire contents of which are hereby incorporated by reference in its entirety.

### TECHNICAL FIELD

The present disclosure relates to the field of display technologies, and in particular to a mask, an evaporation system, and a preparation method for the mask.

### BACKGROUND

In the related art, during a preparing process of a display panel, it is generally necessary to evaporate a material to be evaporated to a predetermined position by means of an opening of a mask.

Currently, there is a problem that the mask for evaporation is not closely attached to a surface of a substrate to be evaporated.

### SUMMARY

The main technical problem solved by the present disclosure is to provide a mask and an evaporation system, which can make the mask attached to a surface of the substrate to be evaporated more closely.

A technical solution adopted by the present disclosure is to provide a mask, comprising: at least one magnetic plate body, defining a plurality of openings; wherein the magnetic plate body comprises a bending body at a periphery of each of the plurality of openings; and the bending body has a certain thickness and width to make the bending body bendable toward a substrate which is configured to be evaporated under an action of a magnetic field generator.

Another solution adopted by the present disclosure is to provide an evaporation system, comprising: the mask described above and a magnetic field generator; wherein the magnetic field generator is configured to adsorb the mask, and the bending body of the mask bends toward a substrate which is configured to be evaporated under an action of the magnetic field generator.

The beneficial effect of the present disclosure is that the magnetic plate body of the mask provided in the present disclosure is provided with a plurality of openings, the magnetic plate body comprises a bending body at a periphery of each of the plurality of openings; and the bending body has a certain thickness and width to make the bending body bendable toward a substrate which is configured to be evaporated under an action of a magnetic field generator. The bending body can be attached to the substrate to be evaporated more closely under the action of the magnetic field generator, thereby reducing the gap between the bending body and the substrate to be evaporated and reducing the vaporization shadow effect, and thus facilitating the display panel to achieve a narrow frame.

### BRIEF DESCRIPTION OF THE DRAWINGS

In order to more clearly explain the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained according to the structures shown in these drawings.

FIG. 1 is a structural schematic view of a mask and a substrate to be evaporated.

FIG. 2 is a structural schematic view of a mask and a substrate to be evaporated according to an embodiment of the present disclosure.

FIG. 3 is a structural schematic view of an attachment between the mask and the substrate to be evaporated shown in FIG. 2 according to an embodiment of the present disclosure.

FIG. 4 is a structural schematic view of an evaporation system according to an embodiment of the present disclosure.

### DETAILED DESCRIPTION

The technical solutions in the embodiments of the present disclosure will be clearly and completely described below in conjunction with the drawings in the embodiments of the present disclosure. Obviously, the described embodiments are only a part of the embodiments of the present disclosure, rather than all the embodiments. Based on the embodiments in the present disclosure, all other embodiments obtained by those skilled in the art without creative work shall fall within the scope of the present disclosure.

At present, the mask for evaporation is generally formed by double-sided etching. When the mask is attached to a surface of the substrate to be evaporated, there is a gap between the mask adjacent to an opening and the surface of the substrate to be evaporated. The gap will cause a shadow effect of evaporation to be more obvious and affect the realization of the narrow frame of the display panel.

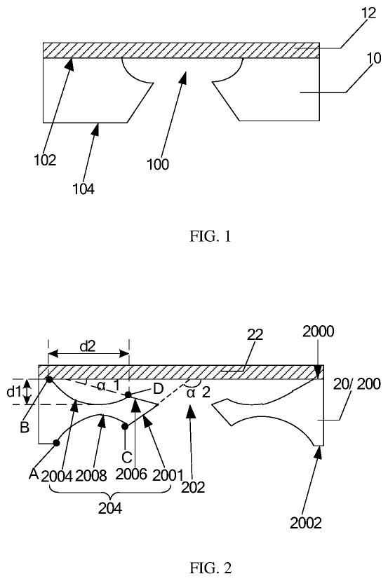

Referring to FIG. 1, the preparation process of a mask 10 (for example, a common metal mask (CMM) universal mask) includes: providing a mask base, wherein the mask base includes a first main surface 102 and a second main surface 104 disposed oppositely; etching the first main surface 102 with an etching solution to form a first etching area (not shown); etching a position of the second main surface 104 corresponding to the first etching area with an etching solution to form a second etching area (not shown); and connecting the first etching area and the second etching area to form an opening 100 of the mask 10. When the mask 10 is attached to the surface of the substrate 12 to be evaporated, since the etching method with the etching solution is applied, there is inevitably a gap (not shown) between the mask adjacent to the opening 100 and the surface of the substrate 12 to be evaporated. The gap will cause the shadow effect of evaporation to be more obvious and affect the realization of the narrow frame of the display panel.

By virtue of the mask and the evaporation system provided by the present disclosure, the mask may be more closely attached to the surface of the substrate to be evaporated.

Referring to FIG. 2 to FIG. 3, a mask 20 includes a magnetic plate body 200. The material of the magnetic plate body 200 may be metal or the like. The magnetic plate body 200 defines a plurality of openings 202 thereof. The magnetic plate body 200 comprises a bending body 204 at a periphery of each of the plurality of openings 202; and the bending body 204 has a certain thickness and width to make the bending body 204 bendable toward a substrate 22 which is configured to be evaporated under an action of a magnetic field generator. The structure of the bending body 204 after bending may be shown in FIG. 3, the bending body 204 may be more closely attached to the substrate 22 to be evaporated under the action of the magnetic field generator, reducing a gap between the bending body 204 and the substrate 22 to be evaporated, reducing a shadow effect of evaporation, and thus achieving a narrow frame of the display panel. In some embodiments, each opening 202 defined on the magnetic plate body 200 may have a central axis, two parts of the opening 202 respectively located at two sides of the central axis are symmetrical about the central axis, and two parts of the bending body 204 located at a periphery of the opening 202 and respectively disposed on two sides of the central axis are symmetrical about the central axis. The above-mentioned configuration can make the structure of the mask 20 simple and easy to realize in process. Of course, in other embodiments, two parts of the opening 202 respectively located at two sides of the central axis are not symmetrical about the central axis, and two parts of the bending body 204 located at a periphery of the opening 202 and respectively disposed on two sides of the central axis are not symmetrical about the central axis, which is not limited in the present disclosure.

Of course, in other embodiments, the mask 20 may also include a frame (not shown), and two ends of each of a plurality of magnetic plate bodies 200 may be fixed to the frame, thereby allowing one mask 20 to evaporate a plurality of areas of the substrate 22 to be evaporated at the same time.

In some embodiments, as shown in FIG. 2, in a thickness direction of the magnetic plate body 200, the bending body 204 may include a first main surface 2000 and a second main surface 2002 which are opposite to each other. The first main surface 2000 comprises a first surface 2004 and a second surface 2006 which are connected to each other. The second surface 2006 is closer to the opening 202 relative to the first surface 2004. For example, the second surface 2006 may be formed during the formation of the opening 202. The second surface 2006 may be configured to attach to the surface of the substrate 22 to be evaporated after the bending body 204 is bent toward the substrate 22 to be evaporated (as shown in FIG. 3). The second surface 2006 is formed during the formation of the opening 202, indicating that the second surface 2006 is adjacent to the opening 202 or directly forms a part of the opening 202. The structure of the bending body 204 is simple in design and easy to implement in the process. During the bending process of the bending body 204, on one hand, due to a small weight of the bending body 204, the bending body 204 is prone to being bent under the action of the magnetic field generator; on the other hand, due to the presence of the first surface 2004, the first surface 2004 can accommodate a bending deformation of the bending body 204 during the bending process and release the stress after the bending deformation.

The width of the bending body 204 is a length between a point on the first surface 2004 furthest from the opening 202 and a point on the magnetic plate body 200 closest to the opening 202 in a direction along the first surface 2004 of the magnetic plate body 200 to the opening 202.

In some embodiments, as shown in FIG. 2, in the thickness direction of the magnetic plate body 200, a height difference d1 between a lowest point and a highest point of the first surface 2004 is less than a width d2 of the first surface 2004. In this embodiment, the first surface 2004 may be a regular or irregular arc surface. The width d2 herein refers to the length between a point on the first surface 2004 closest to the opening 202 and a point on the first surface 2004 furthest from the opening 202 in the direction along the first surface 2004 of the magnetic plate body 200 to the opening 202. The above configuration can make the bending body 204 corresponding to the first surface 2004 easier to bend under the action of a magnetic force of the magnetic field generator.

In some embodiments, the first surface 2004 may include an arc surface. The arc surface may be a partial arc surface on a regular sphere, or a partial arc surface on a regular ellipsoid. Of course, in other embodiments, the arc surface may also be a partial arc surface on an irregular curved body, which is not limited in the present disclosure. The above-mentioned arc surface configuration can make the bending portion 204 corresponding to the first surface 2004 easier to bend under the action of the magnetic force of the magnetic field generator, and release the stress after the bending deformation.

In the embodiment, the first surface 2004 may be the arc surface. Of course, in other embodiments, the first surface 2004 may also be other. For example, an area of the first surface 2004 which is prone to being bent is arranged as an arc surface, and other areas are arranged as flat surfaces, for example, the area of the first surface 2004 which is prone to being bent is arranged at a middle position of the first surface 2004. For another example, the first surface 2004 is a flat surface.

Further, the second surface 2006 may be a flat surface, and the included angle α1 between the second surface 2006 and the surface of the substrate 22 to be evaporated may be an acute angle, for example, 30°, 45°, etc. The above configuration can make the second surface 2006 attached to the surface of the substrate 22 to be evaporated more closely after the bending body 204 is bent, thereby further reducing the shadow effect of evaporation. Of course, in other embodiments, the second surface 2006 may also be an arc surface, and the radian of the second surface 2006 is less than the radian of the first surface 2004. The above configuration can also make the second surface 2006 attached to the surface of the substrate 22 to be evaporated more closely after the bending body 204 is bent, thereby further reducing the shadow effect of evaporation.

In other embodiments, referring to FIG. 2 again, the second main surface 2002 of the bending body 204 comprises a third surface 2008 and a fourth surface 2001 which are connected to each other. The fourth surface 2001 is closer to the opening 202 relative to the third surface 2008. For example, the fourth surface 2001 may be formed during the formation of the opening 202. The fourth surface 2001 is formed during the formation of the opening 202, indicating that the fourth surface 2001 is adjacent to the opening 202 or directly forms a part of the opening 202. In this way, the structural configuration of the bending body 204 is simple, and the process is easy to implement. Moreover, the above configuration of the third surface 2008 and the fourth surface 2001 of the second main surface 2002 can make the weight of the bending body 204 disposed around the opening 202 lighter, preventing the mask 20 from failing to attach to the surface of the substrate 22 to be evaporated under the action of the magnetic field generator. Furthermore, the above configuration of the third surface 2008 and the fourth surface 2001 of the second main surface 2002 can reduce the bending stress, such that the bending body 204 can be bent more easily. In some embodiments, as shown in FIG. 2, the third surface 2008 may include an arc surface, the arc surface may be a partial arc surface on a regular sphere, or a partial arc surface on a regular ellipsoid. Of course, in other embodiments, the arc surface may also be a partial arc surface on an irregular curved body, which is not limited in the present disclosure. The above-mentioned arc surface configuration can make the bending portion 204 corresponding to the third surface 2008 bent more easily under the action of the magnetic force of the magnetic field generator.

Further, when the first surface 2004 and the third surface 2008 are both arc surfaces, the radian of the third surface 2008 is greater than the radian of the first surface 2004. The above configuration can make the entire bending body 204 bent more easily under the action of the magnetic force of the magnetic field generator.

In the embodiments, the third surface 2008 may be an arc surface. Of course, in other embodiments, the third surface 2008 may also be other. For example, an area of the third surface 2008 which is prone to being bent is arranged as an arc surface, and other areas are arranged as flat surfaces, the area of the third surface 2008 which is prone to being bent may be arranged at a position same as a location of the area of the first surface 2004 which is prone to being bent. For another example, the third surface 2008 is a flat surface.

Further, the fourth surface 2001 may be a flat surface, and the included angle α2 between the fourth surface 2001 and the surface of the substrate 22 to be evaporated may be an obtuse angle, for example, 120°, 135°, etc. The included angle α2 may be configured according to an evaporation angle of the evaporation device during evaporation, which is not limited in the present disclosure.

In some embodiments, in a direction perpendicular to the first main surface 2000, a first end A of the third surface 2008 furthest from the opening 202 is flush with a second end B of the first surface 2004 furthest from the opening 202. In other embodiments, the first end A is closer to the opening 202 relative to the second end B. The above configuration can make the entire bending body 204 bent more easily under the action of the magnetic force of the magnetic field generator. And/or, in the direction perpendicular to the first main surface 2000, a third end C of the third surface 2008 closest to the opening 202 is flush with a fourth end D of the first surface 2004 closest to the opening 202. In other embodiments, the third end C is further away from the opening 202 than the fourth end D. The above configuration can also make the entire bending body 204 bent more easily under the action of the magnetic force of the magnetic field generator. Of course, in other embodiments, the first main surface 2000 and/or the second main surface 2002 of the bending body 204 may also include other surfaces. The other surfaces may be spaced apart from the first surface 2004 or the third surface 2008, or may be connected to the first surface 2004 or the third surface 2008. The other surfaces may be all arc surfaces, or some of the other surfaces may be arc surfaces, etc., which is not limited in the present disclosure.

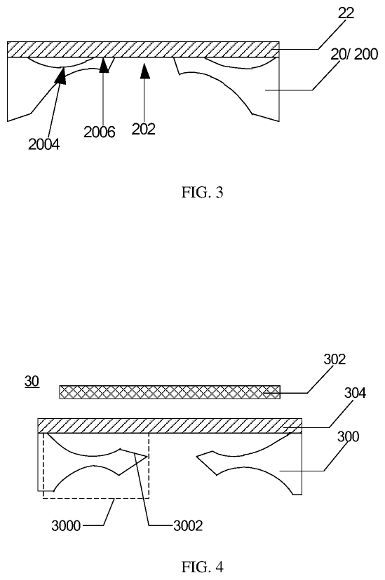

Referring to FIG. 4, FIG. 4 is a structural schematic view of an evaporation system according to an embodiment of the present disclosure. The evaporation system 30 includes: the mask 300 according to any of the above embodiments and the magnetic field generator 302. The magnetic field generator 302 is configured to adsorb the mask 300, and the bending body 3000 of the mask 300 bends toward a substrate 304 which is configured to be evaporated under the action of the magnetic field generator 302. In the embodiments, the magnetic field generator 302 may be an electromagnetic plate or the like. During the evaporation process, the magnetic field generator 302 and the mask 300 are disposed on two opposite sides of the substrate 304 to be evaporated. The second surface 3002 of the bending body 3000 of the mask 300 is attached to the surface of the substrate 304 to be evaporated more closely under the action of the magnetic field generator 302, reducing the gap between the bending body 3000 and the substrate 304 to be evaporated, reducing the shadow effect of vaporization, and thus facilitating the realization of a narrow frame of the display panel.

Furthermore, in the embodiments, the evaporation system 30 may further include an evaporation device (not shown) for providing a material to be evaporated. In the actual evaporation process, the evaporation device may be disposed on a side of the mask 300 away from the substrate 304 to be evaporated.

The mask provided by the present disclosure will be further described from the perspective of the preparation method in conjunction with FIG. 2 below. The method for preparing the mask provided in the present disclosure includes steps as followed.

Firstly, providing a magnetic plate body 200, wherein the magnetic plate body 200 includes a first main surface 2000 and a second main surface 2002 which are opposite each other, and the first main surface 2000 may be a flat surface entirely, and the second main surface 2002 may be a flat surface entirely.

Secondly, etching the magnetic plate body 200 with an etching solution, wherein the magnetic plate body 200 includes a plurality of openings 202 and a bending body 204 at a periphery of each of the plurality of openings after etching, and the bending body 204 has a certain thickness and width to make the bending body 204 bendable toward a substrate 22 which is configured to be evaporated under an action of a magnetic field generator.

In the embodiments, after etching with the etching solution, in a thickness direction of the magnetic plate body 200, the first main surface 2000 includes a first surface 2004 and a second surface 2006 which are connected to each other. The second surface 2006 is closer to the opening 202 relative to the first surface 2004. The second main surface 2002 includes a third surface 2008 and a fourth surface 2001 which are connected to each other. The fourth surface 2001 is closer to the opening 202 relative to the third surface 2008. The bending body 204 is formed by a portion of the magnetic plate body 200 including the first surface 2004, the second surface 2006, the third surface 2008 and the fourth surface 2001.

In some embodiments, the process of forming the opening 202 and the bending body 204 by etching with the etching solution may be as followed.

A. A first etching area (not shown) is formed by etching the first main surface 2000 with the etching solution. A second etching area (not shown) is formed by etching the second main surface 2002 at a position corresponding to the first etching area with the etching solution. The first etching area and the second etching area are connected, a part of the first etching area and a part of the second etching area which are contiguous to each other form the opening 202, a remaining part of the first etching area forms the second surface 2006, and a remaining part of the second etching area forms the fourth surface 2001.

B. The first surface 2004 is formed by etching the first main surface 2000 with the etching solution, the first surface 2004 is located at a side of the second surface 2006, and the first surface 2004 is connected to the second surface 2006. The third surface 2008 is formed by etching the second main surface 2002 with the etching solution, the third surface 2008 is located at a side of the fourth surface 2001, and the third surface 2008 is connected to the fourth surface 2001.

In other embodiments, the process of forming the opening 202 and the bending body 204 by etching with the etching solution may be as followed.

A. A magnetic substrate is provided. The magnetic substrate includes the first main surface 2000 and the second main surface 2002 which are opposite to each other. The first main surface 2000 may be a flat surface entirely, and the second main surface 2002 may be a flat surface entirely.

B. The first main surface 2000 is etched with the etching solution to form a first etching area (not shown) and the first surface 2004 which are connected to each other.

C. The second main surface 2002 is etched with the etching solution to form a second etching area and the third surface 2008 which are connected to each other. The position of the first etching area and the position of the second etching area are corresponding to each other, and a part of the first etching area and a part of the second etching area are connected to form the opening 202. A remaining part of the first etching area forms the second surface 2006, and a remaining part of the second etching area forms the fourth surface 2001. The position of the first surface 2004 and the position of the third surface 2008 are corresponding to each other.

It can be seen from the above preparation method that the process of preparing the mask 20 provided by the present disclosure is relatively simple and easy to implement.

The above are only implementations of the present disclosure, and do not limit the scope of the present disclosure. Any equivalent structure or equivalent process transformation made using the content of the description and drawings of the present disclosure, or direct or indirect application in other related technical fields, is included in the scope of the disclosure.

What is claimed is:

1. A mask, comprising:
at least one magnetic plate body, defining a plurality of openings;
wherein the magnetic plate body comprises a bending body at a periphery of each of the plurality of openings; and the bending body has a certain thickness and width to make the bending body bendable toward a substrate which is configured to be evaporated under an action of a magnetic field generator.

2. The mask according to claim 1, wherein the bending body comprises a first main surface and a second main surface opposite to the first main surface;
the first main surface has a first surface and a second surface connected to each other;
the second surface is closer to a corresponding opening relative to the first surface;
the second surface is configured to attach to a surface of the substrate to be evaporated after the bending body is bent toward the substrate to be evaporated.

3. The mask according to claim 2, wherein in a thickness direction of the magnetic plate body, a height difference between a lowest point and a highest point of the first surface is less than a width of the first surface.

4. The mask according to claim 2, wherein the first surface comprises an arc surface.

5. The mask according to claim 4, wherein the second surface is a flat surface.

6. The mask according to claim 4, wherein the second surface is an arc surface, and a radian of the second surface is less than a radian of the first surface.

7. The mask according to claim 4, wherein the second main surface comprises a third surface and a fourth surface which are connected to each other, and the fourth surface is closer to the corresponding opening than the third surface.

8. The mask according to claim 7, wherein the third surface comprises an arc surface.

9. The mask according to claim 8, wherein in a direction perpendicular to the first main surface, a first end of the third surface furthest from the corresponding opening is aligned with a second end of the first surface furthest from the corresponding opening.

10. The mask according to claim 8, wherein
a first end of the third surface furthest from the corresponding opening is closer to the corresponding opening than a second end of the first surface furthest from the corresponding opening.

11. The mask according to claim 8, wherein in a direction perpendicular to the first main surface, a third end of the third surface closest to the corresponding opening is aligned with a fourth end of the first surface closest to the corresponding opening.

12. The mask according to claim 8, wherein a third end of the third surface closest to the corresponding opening is further away from the corresponding opening than a fourth end of the first surface closest to the corresponding opening.

13. The mask according to claim 8, wherein a radian of the third surface is greater than a radian of the first surface.

14. The mask according to claim 1, further comprising a frame; wherein two opposite ends of each magnetic plate body are fixed to the frame.

15. An evaporation system, comprising: the mask according to claim 1 and a magnetic field generator;
wherein the magnetic field generator is configured to adsorb the mask, and the bending body of the mask bends toward a substrate which is configured to be evaporated under an action of the magnetic field generator.
